(19) United States
(12) Patent Application Publication
(10) Pub. No.: US 2026/0213735 A1
(43) Pub. Date: Jul. 23, 2026

(54) MULTIPLEXER TO CONNECT ANY OF MULTIPLE INPUT SIGNALS TO AN OUTPUT PATH

(71) Applicant: Shaoxing Yuanfang Semiconductor Co., Ltd., Shaoxing (CN)

(72) Inventors: Madhusudan Srinivasan, Bangalore (IN); Raja Prabhu J., Bangalore (IN); Harshit Rathore, Bangalore (IN); Laxmi Choudhary, Bangalore (IN); Kranthi Kadiyala, Bangalore (IN)

(21) Appl. No.: 19/361,039

(22) Filed: Oct. 17, 2025

(30) Foreign Application Priority Data
Jan. 22, 2025 (IN) 202541005303

(51) Int. Cl. H03H 11/34; H03K 17/00

(52) U.S. Cl. CPC H03H 11/34; H03K 17/002

(57) ABSTRACT

A multiplexer to connect any one of multiple input signals to an output path includes multiple transistors, a set of switches and a control unit. Each transistor has a control terminal and a pair of current terminals. The terminals of the pair are respectively connected to a constant reference potential and an output node at one end of the output path. Each transistor is operable to provide a corresponding forwarded signal at the output node corresponding to an input signal if the input signal is received at the control terminal, and to tri-state the output node if the control terminal is connected to a constant reference potential. Based on a received control value, the control unit controls the set of switches to couple the corresponding input signal to the control terminal of only one transistor, while connecting the control terminals of the remaining transistors to a constant reference potential.

### PRIORITY CLAIM

The instant patent application is related to and claims priority from the co-pending India provisional patent application entitled, “Low Noise/Cross-Talk Output Clock Distribution”, Serial No.: 202541005303, Filed: 22 Jan., 2025, Attorney docket no.: AURA-370-INPR, which is incorporated in its entirety herewith to the extent not inconsistent with the description herein.

### Related Application

The present application is related to the co-pending application Entitled, “Reducing Cross-Talk among Signals”, Serial Number: UNASSIGNED, filed on even date herewith, attorney docket number: AURA-076-US, naming the same inventors as in the present application, and which is incorporated in its entirety herewith to the extent not inconsistent with the description herein.

### BACKGROUND

### Technical Field

Embodiments of the present disclosure relate generally to signal transmission in wireline media, and more specifically to a multiplexer to connect any one of multiple input signals to an output path.

### Related Art

A multiplexer (MUX) is a circuit that has multiple input nodes and one output node, and is controllable to select one of multiple input signals received on corresponding input nodes, and to forward (pass) the selected input signal on the output node. A multiplexer receives a ‘select’ signal that indicates which of the input signals is to be forwarded on the output node.

Aspects of the present disclosure are directed to a multiplexer.

### BRIEF DESCRIPTION OF THE VIEWS OF DRAWINGS

Example embodiments of the present disclosure will be described with reference to the accompanying drawings briefly described below.

FIG. 1 is a block diagram of an example device in which several aspects of the present disclosure can be implemented.

FIG. 2 is a diagram illustrating the implementation of a multiplexer according to aspects of the present disclosure in an embodiment.

FIG. 3 is a diagram illustrating the implementation details of a one-half portion of a differential driver used in a multiplexer, in an embodiment of the present disclosure.

FIG. 4 is a diagram illustrating the implementation of a signal-distribution channel employing multiplexers designed according to aspects of the present disclosure, in an embodiment.

In the drawings, like reference numbers generally indicate identical, functionally similar, and/or structurally similar elements. The drawing in which an element first appears is indicated by the leftmost digit(s) in the corresponding reference number.

### DETAILED DESCRIPTION

### 1. Overview

A multiplexer to connect any of multiple input signals to an output path includes multiple transistors, a set of switches and a control unit. Each transistor has a control terminal and a pair of current terminals. The terminals of the pair are respectively connected to a constant reference potential and an output node at one end of the output path. Each transistor is operable to provide a corresponding forwarded signal at the output node corresponding to an input signal if the input signal is received at the control terminal, and to tri-state the output node if the control terminal is connected to a constant reference potential. Based on a received control value, the control unit controls the set of switches to couple the corresponding input signal to the control terminal of only one transistor, while connecting the control terminals of the remaining transistors to a constant reference potential.

In an embodiment, a multiplexer has multiple drivers, with each driver receiving a corresponding input signal. Only one of the drivers provides a forwarded signal at the output node corresponding to a corresponding input signal. Each driver is implemented as a source-series terminated (SST) differential inverter.

Multiple numbers of a multiplexer are used to build a signal distributor that allows any of multiple signals received as inputs to be provided at any one of output ports of the signal distributor.

Several aspects of the present disclosure are described below with reference to examples for illustration. However, one skilled in the relevant art will recognize that the disclosure can be practiced without one or more of the specific details or with other methods, components, materials and so forth. In other instances, well known structures, materials, or operations are not shown in detail to avoid obscuring the features of the disclosure. Furthermore, the features/aspects described can be practiced in various combinations, though only some of the combinations are described herein for conciseness.

### 2. Example Device

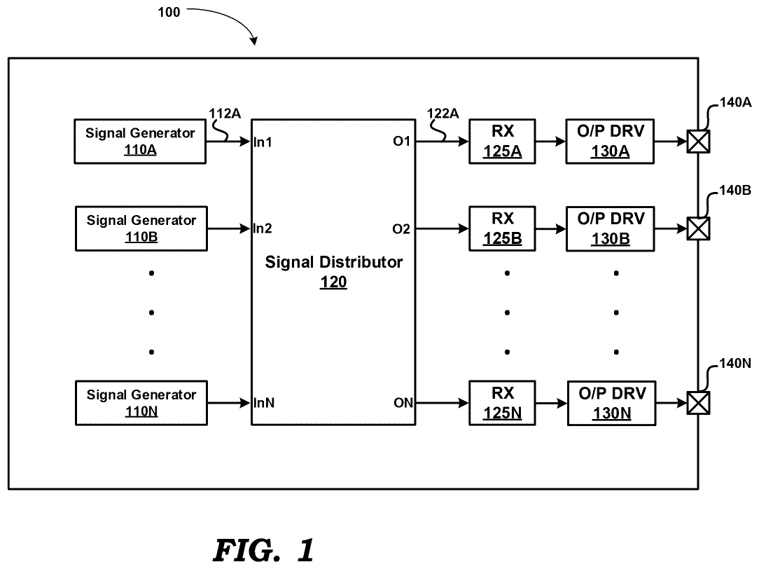

FIG. 1 is a block diagram of an example device in which several aspects of the present disclosure can be implemented. FIG. 1 shows relevant portions of an integrated circuit (IC) 100 (which may be a system-on-chip (SOC)), which is in turn shown containing signal generators 110A through 110N, signal distributor 120, receivers (Rx) 125A through 125N, output drivers (O/P DRV) 130A through 130N and package pins 140A through 140N.

According to the convention used herein, signal generators 110A through 110N are collectively or individually referred by reference numeral 110, as will be clear from the context. Similar convention is used for other similar components as well. Other portions of IC 100 such as power supplies, oscillators, etc., are not shown in FIG. 1 in the interest of clarity and conciseness. Further, the specific blocks of FIG. 1 are shown merely by way of example. Various aspects of the present disclosure can be implemented in other devices and environments too.

In the example of FIG. 1, each of signal generators 110A through 110N is a phase locked loops (PLL) and generate clock signals. The clock signals described herein can have frequencies ranging from a few Hertz (Hz) to several giga Hertz (GHz). The clocks can have a waveform of square waves (or non-sinusoidal waves, in general), sinusoidal waves, etc., although the description provided herein assumes square waves.

While the following description is provided with respect to square-wave clock signals (digital signals), it should be understood that features of the present disclosure are applicable to other types of signals such as analog signals, information-bearing (modulated) signals such as, for example, video signals, modulated RF (radio-frequency) signals used in wireless equipment, etc. In general, the features disclosed herein are of particular use when the nature of the signals (specifically their frequency-content and/or rise/fall times) are such that length of the path (electrical traces) on which signals flow need to be treated as transmission lines. However, it is noted here that the features disclosed herein can be applied even in non-transmission-line environments, in which there are no constraints on the source and load impedances of the driver and receiver respectively to have a certain relationship with the characteristic impedance of the corresponding transmission line (Zo) employed.

As is well known in the relevant arts, if a wire or a conducting path has a length that is much greater than (for example, greater than 10 times) the period of the highest frequency-component in the signal (or, for square wave signals, the rise (or fall) time of the edges of the signal), then the wire is treated as a transmission line. The transmitter and the receiver at opposite ends of the wire, as well as the wire itself, need to have matched controlled-impedances, as is also well known in the relevant arts. In IC 100, the electrical path from the output of a PLL 110 to an output pin 140 (or the corresponding signal pad of the die) qualifies as a transmission line due to its length necessitated by the layout of the various circuits and blocks (including those not shown in FIG. 1) in IC 100 and the routing of traces between them, and to the signal pads and package pins.

Each of the paths from the output of a signal generator 110 to a pin of IC 100 is described herein to be a differential path carrying differential signals. However, such paths and signals can also be single-ended signals with corresponding modifications to the circuits and blocks described herein, as would be apparent to one skilled in the relevant arts upon reading the disclosure herein.

Each of signal generators 110A-110N is a phase locked loop (PLL) in the example provided herein, and generates a clock signal at its output node. In an embodiment, the internal blocks (phase detector, low-pass filter, etc.) in each PLL are single-ended circuits, and the generated clock signals are single-ended clocks. However, in an alternative embodiment, IC 100 employs fully-differential PLLs that generate differential clock signals. When the PLL circuitry in a PLL generates a single-ended clock signal, a single-ended to differential converter circuit is employed (not shown) in the PLL to convert the single-ended clock signal to differential form.

In the embodiments described herein, signal distributor 120, receivers 125 and output drivers 130 employ differential circuits and operate on differential signals, and each of pins 140 is a pair of pins. However, in an alternative embodiment, all the components and blocks of FIG. 1 are single-ended circuits, and each of pins 140 is a single pin. The output of a PLL 110 is connected to a corresponding input port of signal distributor 120. Thus, the clock signal generated by PLL 110A is shown as being provided to input port In1 of signal distributor 120 via path 112A.

Each of receivers (Rx) 125A-125N is connected to a corresponding one of the output ports of signal distributor 120. To illustrate, Rx 125A is shown connected to output port O1 via path 122A. Receivers 125 receive a corresponding clock signal from an output port of signal distributor 120 and amplify the clock signal to a desired level. For example, when the clocks are square-wave signals with binary logic levels, receivers 125 may be designed to amplify the received clock signals to rail-to-rail levels. The received clock signals may have low signal-swing levels (low amplitude) either due to having been generated as low signal-swing signals and/or may have been distorted by noise and/or signal reflections. Receivers 125 forward the respective amplified signals (after internal buffering) to a corresponding output driver in output drivers 130. To illustrate, Rx 125A is shown connected to output driver 130A of drivers 130.

Output drivers (DRV) 130 contain multiple drivers 130A-130N, which respectively receive a respective amplified-and-buffered clock signal and drive the amplified-and-buffered clock signal with the desired strength to corresponding output pins 140 of IC 100.

In the example embodiments described herein, the number of signal generators 110 equals the number of output pins 140. However, in some alternative embodiments, the number of signal generators can be smaller/larger than the number of output pins 140. While, the end-points for the clock signals are noted herein as either an IC pin 140 (or at least the receiver 125 that is connected to that pin via an output driver 130), in and other embodiment, the end-points are internal nodes (or ports) within IC 100. Such internal nodes could, for example, be nodes on which other circuits/devices such as processors or simpler logic blocks receive their clock inputs.

Signal distributor 120 has multiple input ports (In1 through InN) and multiple output ports (O1 through ON). Although the number of input ports and output ports are each noted herein as equal (to N), in general, their numbers can be unequal. Thus, the number of input ports can be less than, equal to, or greater than the number of output ports. Correspondingly, in general, the number of signal generators 110 can be less than, equal to, or greater than the number of end points (here, pins 140 of IC 100). The techniques of the present disclosure, including the design of a multiplexer, apply irrespective of the specific number of input ports and output ports.

Signal distributor 120 receives a corresponding clock signal as input on each of its input ports. Signal distributor 120 is designed to selectively connect an input port to any (one) of the output ports. The selection is by generating respective control signals which are not shown in FIG. 1, but can be generated as external input to IC 100, from a non-volatile memory unit storing configuration data within IC 100 or other known techniques. Each of the input ports can be connected to any one of the output ports.

Signal distributor 120 may be implemented to provide such connections between input and output ports using techniques designed to minimize routing congestion, and thereby crosstalk, between or among clock signals on the connecting routes/signal-traces/paths within it. Some example implementations of signal distributor 120 are cross-point switch matrix and analog multiplexers. A connecting trace from an input port to an output port in signal distributor 120, and further from the output port to a receiver 125 is implemented to provide a controlled impedance. The connecting traces (paths in general) can be implemented in a known way, such as for example, as strip-lines.

Signal distributor 120 is implemented using a set of multiplexers, each of which is implemented as described next.

### 3. Multiplexer

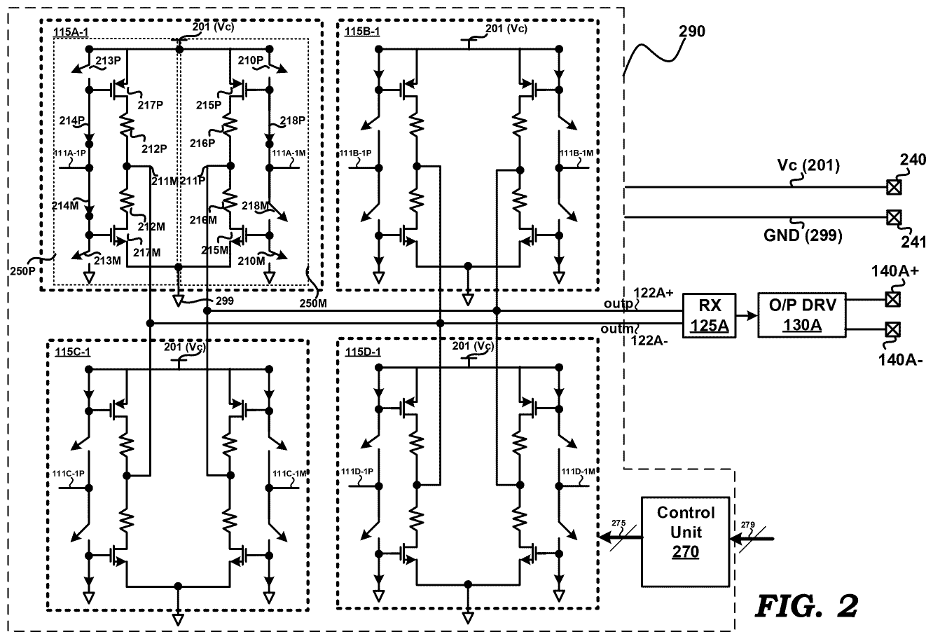

FIG. 2 is a diagram illustrating the implementation of a multiplexer according to several aspects of the present disclosure, in an embodiment. In the Figure, a 4:1 multiplexer 290 is shown containing drivers 115A-1, 115B-1, 115C-1 and 115D-1 and control unit 270. Multiplexer (MUX) 290 receives four inputs signals and operates to forward a selected one of the four inputs signals as an output signal. Control unit 270 of MUX 290 generates ‘select’ signals on path 275, to select a specific one of the four inputs signals for forwarding as the output signal. The specific details of FIG. 2 are shown merely by way of illustration. In general, a MUX implemented as described herein can be a N:1 multiplexer, with N being any integer greater than 1.

Merely for illustration and continuity with FIG. 1, receiver 125A, output driver 130A and pins 140+/140− of FIG. 1 are also shown in FIG. 2. However, it must be understood that a multiplexer implemented according to one or more aspects of the present disclosure can be used in other systems and environments and in combination with other components and circuits too.

As noted above, in the examples provides herein, the input signals to MUX 290 are square-wave clock signals. However, in general, the input signals can be analog signals or digital signals. In the examples provided herein, the frequency-content and/or rise/fall times of the input signals are such that length of the path (electrical traces) on which signals flow from the output node of MUX 290 to an end-point (e.g., a receiver, as in FIG. 1) the path needs to be treated as a transmission line, and the design of the multiplexer needs to take into account transmission-line effects. Additionally, it is generally desirable to minimize the size/area needed for implementing the multiplexer.

Referring to FIG. 2, MUX 290 is shown consisting of four drivers 115A-1, 115B-1, 115C-1 and 115D-1. The input nodes of the drivers (which are also the input nodes of MUX 290) receive respective input signals that are to be multiplexed. The output nodes of all the four drivers are connected to each other and to the output node of the MUX.

In FIG. 2, node-pairs 111A-1P/111A-1M, 111B-1P/111B-1M, 111C-1P/111C-1M and 111D-1P/111D-1M are the input nodes of drivers 115A-1, 115B-1, 115C-1 and 115D-1 respectively. The input nodes of each of drivers 115A-1, 115B-1, 115C-1 and 115D-1 is connected to the output of a corresponding PLL 110. Thus, assuming N of FIG. 1 equals 4, there would be four of PLLs 110 there. In the example, the input nodes of drivers 115A-1, 115B-1, 115C-1 and 115D-1 are connected to the output of PLLs 110A, 110B, 110C and 110D respectively, and receive the corresponding clock signal from the PLLs.

Node-pair 211P/211M represents the output node of driver 115A-1. The output nodes of the other drivers are not numbered in the interest of clarity. All the output nodes (or node-pairs) are connected to output node 122A+/122A− (outp/outm) of the MUX. Output node 122A+/112A− is connected to RX 125A, which is connected to output driver 130A, which is connected to pin 140A+/140−.

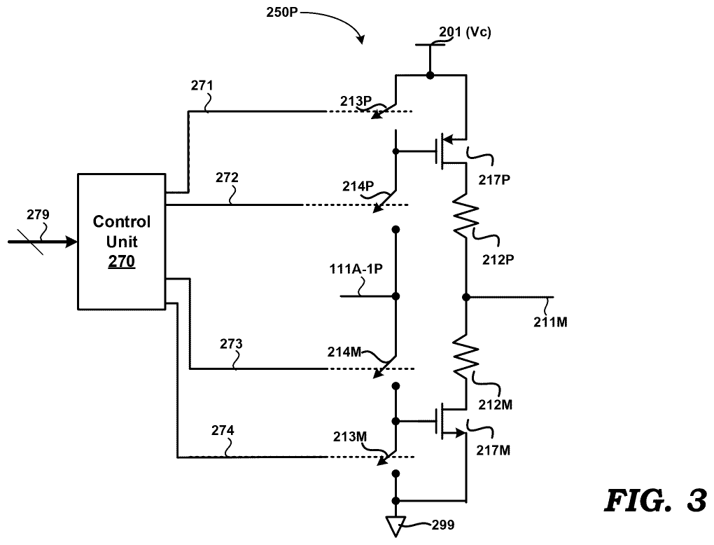

Driver 115A-1 is shown implemented as a differential inverter made of a pair of single-ended inverters 250P and 250M. Single-ended inverter 250P is also shown in FIG. 3, and is shown there containing PMOS (P-channel metal-oxide semiconductor field effect transistor (MOS)) 217P, NMOS (N-channel MOS) 217M, resistors 212P, 212M and switches 213P, 214P, 213M and 214M. The inverter is powered by a supply with voltage Vc (201). Terminal 299 (GND) represents a ground terminal. In an embodiment, each of switches 213P, 214P, 214M and 213M is implemented as a MOS transistor.

When switches 214P and 214M are closed, with switches 213P and 213M open, the input signal 111A-1P is applied as a transistor-control signal at the gate terminals of transistors 217P and 217M. Accordingly, inverter 250P operates to generate a signal on output node 122A− as the (logical) inverse of the signal at input node 111A-1P. The signal on output node 122A− is viewed as a forwarded signal, representing the input signal 111-A-1P (though in inverted form). When switches 214P and 214M are open, with switches 213P and 213M closed, both PMOS 217P and NMOS 217M are switched off, and node 122A− is in high-impedance state (tri-state).

Also shown in FIG. 3 is control unit 270. Control unit 270 receives one or more inputs on path 279, with the inputs indicating which of the input signals to MUX 290 is to be selected and forwarded to the output node of MUX 290. Input 279 may be received from a unit external to IC 100 (e.g., from a user-operated unit) or from another block in IC 100 (or within control unit 270 itself) such as a configuration memory storing configuration bits indicating the selection to be made in MUX 290. Other ways of providing such inputs can also be used instead as would be apparent to one skilled in the relevant arts. Based on the inputs received or on local configuration data, control unit 270 generates signals on paths 271, 272, 273 and 274 to open or close switches 213P, 214P, 214M and 213M respectively. Paths 271-274 are contained in paths 275 in FIG. 2.

Single-ended inverter 250M (FIG. 2) is implemented similar to inverter 250P, and is shown containing PMOS 215P, NMOS 215M, resistors 216P, 216M and switches 210P, 218P, 210M and 218M. Inverter 250M operates in a manner similar to that described above with respect to inverter 250P. Inverter 250M also receives corresponding switch-control signals from control unit 270 for operating the corresponding switches to be open or closed, although they are not shown in the Figures.

Drivers 115B-1, 115C-1 and 115D-1 are implemented, as well as operate, in a manner similar to that described above with respect to driver 115A-1, and are shown in FIG. 2, but their components are not numbered there. Although not shown, each of drivers 115B-1, 115C-1 and 115D-1 also receives corresponding switch-control signals from control unit 270 for operating the corresponding switches therein to be open or closed.

It may be appreciated that MUX 290 can handle small-amplitude analog signals with appropriate biasing. For instance, differential signals with a common-mode value of half of voltage 201, i.e., (0.5*Vc), and relatively small voltage-swing about the common-mode level can be multiplexed using MUX 290.

Referring now to FIG. 2, the switch positions in each of the drivers shown there of MUX 290 are such as to enable driver 115A-1 to drive the clock signal received from PLL 110A on inputs 111A-1P/111A-1M onto the output path 122A+/122A−, while tri-stating the outputs of the drivers 115B-1, 115C-1 and 115D-1. Thus, by operating the appropriate switches of the drivers of a multiplexer, the desired input signal is forwarded as the output of the multiplexer. By employing the appropriate number of drivers per MUX, and connecting the output (clock signal) of respective PLLs 110 to the respective drivers of a MUX, an N:1 MUX can be obtained. All the other MUXes needed to implement signal distributor 120 are also implemented in a similar manner, as described below.

It is noted here that when MUX 290 is to handle single-ended signals, i.e., when either both the input signals to and output signal from MUX 290 are single-ended or when the input signals are differential signals but the output signal is single-ended, the output of MUX 290 is provided across one of terminals 122A+ (outp) and 122A− (outm) and GND (299) or Vc (201), with such an output often termed a ‘3-wire output’. Additionally, when the input signals are single-ended, ground (290) or Vc (201) needs to be connected to the source of the input signals. To illustrate, MUX 290 may receive four single-ended input signals on terminals 111A-P, 111B-1P, 111C-1P and 111D-1P and forward a specific one of the four input signals as an output on an output path that includes either the pair of nodes 122A− (outm) and GND (299) or the pair of nodes 122A− (outm) and Vc (201), depending on the value of resistances of the resistors of MUX 290, which are typically all equal). Thus, to support differential as a well as single-ended outputs, in addition to the node-pair 122A+ and 122A−, ground and Vc are also wired (connected) to the corresponding receiver that is to receive the output of MUX 290. Thus, in general, the term ‘output path’ of MUX 290 includes GND (299) and Vc (201) in addition to nodes 122+ and 122−. Thus, in corresponding embodiments, GND (299) and Vc (201) are also provided as outputs of MUX 290 as well as on output pins of IC 100 as also indicated in FIG. 2.

When employed in the example environment of FIG. 1, and more specifically in signal distributor 120, each driver of MUX 290 is implemented to have an output impedance (source termination) that has a value that is selected relative to the characteristic impedance of the wire/electrical-path from the driver to the corresponding receiver and via the multiplexer in signal distributor 120. Such ‘impedance matching’ is well known in the art and is needed to minimize signal distortion due to reflections in the transmission lines on which the signals pass, as well as any potential cross-talk that such signal distortions may cause when one or more other wires carrying clock signals (or other types of signals) are in close proximity.

In FIG. 2, each of the drivers shown there is implemented as a source-series terminated (SST) differential inverter. The differential output impedance of a driver there 2 R ohms, wherein R is the resistance of each of the four resistors (e.g., 212P, 212M, 216P and 216M of driver 115A-1) in the driver. In an embodiment, the differential output impedance (2 R) of a driver is implemented to be less than the characteristic impedance (Zo) of the transmission path/channel from the driver to the corresponding receiver (RX 125A in FIG. 2). The source impedance is deliberately made less than the channel impedance with the goal of minimizing cross-talk. In an embodiment, the output impedance of a driver of a MUX is selectable among one of several values. In an embodiment, the differential output impedance equals Zo/2. All the multiplexers used to implement signal distributor 120 are made of drivers that are similarly implemented as SST differential inverters.

A multiplexer implemented as described above has several advantages over some presently available multiplexer implementations. For example, a prior and commonly used multiplexer for multiplexing signals has additional switches in the signal-path from the MUX to a receiver, i.e., in the output path of a MUX. Referring to FIG. 3, in the prior multiplexer, an additional switch is placed in series between PMOS 217P and resistor 212P and another switch is placed in series between NMOS 217M and resistor 212M. Switches 213P and 213M are not implemented and the nodes they would otherwise connect when closed are left permanently disconnected/open. Switches 214P and 214M are also not used, and the nodes they would otherwise connect when closed are left permanently connected/closed. Thus, signal 111A-1P is always available as input to the inverter. When input is to be forwarded to output 1222A− (as a logical inverse), then the pair of additional switches noted above are in switched ON (closed condition), thereby providing the logical inverse of the input at the output. When the output is to be tri-stated, the additional switches are switched OFF (open condition). The prior MUX is made of multiple drivers, but with each driver employing switches as noted above in the signal (or output) path.

One drawback with the prior MUX is that the additional switches, being in the signal path, need to handle the power/current of the signal, which for drivers is typically high. Therefore, the additional switches need to be implemented as relatively large-sized switches (e.g., MOS transistors). The additional area needed is in itself a drawback. Another drawback is that each of the additional switches introduces associated parasitic capacitances in the output (signal) path. These parasitic capacitances affect the output signal of the MUX even when the corresponding switches are OFF. As a result, it is generally more difficult to provide a controlled output-impedance to the driver. Further, greater the number of drivers per MUX (i.e., greater the value of N in the N:1 MUX), greater will be the total parasitic capacitance of the driver output path, thereby rendering impedance control of the driver's output impedance and therefore impedance matching with the output path's characteristic impedance that much more difficult.

On the other hand, a MUX implemented according to aspects of the present disclosure (e.g., MUX 290 of FIG. 2) do not have additional switches in its output path. Instead, each driver of the MUX contains eight switches that are in the path of the differential inputs of the driver. Being at the inputs, the switches do not need to handle large currents. Therefore, their sizes are relatively smaller. Further, since the additional switches are not in the output-path, no additional parasitic capacitances are introduced in the output path, and the output impedance of the SST driver can be precisely controlled and is easier to realize.

Multiplexers implemented in the manner described above with respect to FIG. 2 and 3 are used to implement signal distributor 120, as described next.

### 4. Signal Distributor

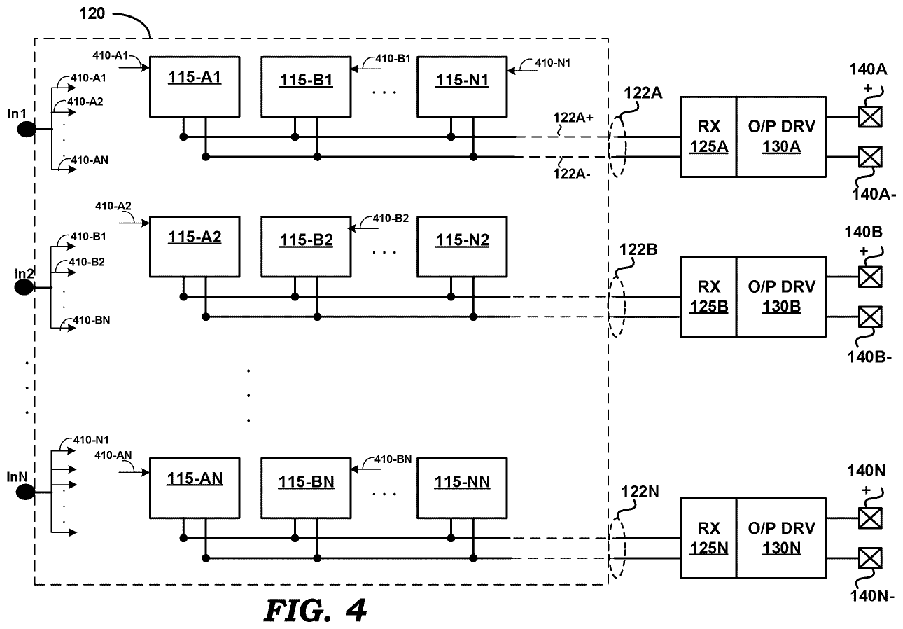

FIG. 4 is a diagram illustrating the implementation details of signal distributor 120 in an embodiment of the present disclosure. Signal distributor 120 is shown containing drivers 115-A1 to 115-N1, 115-A2 to 115-N2 through 115-AN to 115-NN. The outputs of each driver in the set of drivers 115-A1 to 115-N1 are permanently wired to path 122A (made of 122A+ and 122A−). Similarly, the outputs of each of the other sets of drivers are hard-wired to the corresponding output path (122B through 122N). Each of paths 122A through 122N terminates respectively at output ports O1 through ON, as also shown in FIG. 4. Also shown in FIG. 4 for clarity are receivers 125, output drivers 130 and pins 140.

Each input port is connected to one driver each of every output path. To illustrate, input port In1 (which receives the clock signal generated by PLL 110A of FIG. 1) is connected to driver 115-A1 on path 410-A1, driver 115-A2 on path 410-A2 and so on, up to driver 115-AN on path 410-An. Input port In2 (which receives the clock signal generated by PLL 110B of FIG. 1) is connected to driver 115-B1 on path 410-B1, driver 115-B2 on path 410-B2 and so on, up to driver 115-BN on path 410-BN. Input port InN is shown connected to driver 115-N1 on path 410-N1. The other connections are not shown in the interest of clarity and conciseness.

Each transmission channel 122 contains an N:1 multiplexer made of N drivers. For example, channel 122A contains an N:1 multiplexer made of drivers 115-A1 through 115-N1. By configuring the switches in the drivers of the multiplexers in signal distributor 120 appropriately (as illustrated with the example of FIG. 2), any of the clock signals generated by PLLs 110 can be provided at any one output port of signal distributor 120 and therefore the corresponding output pin 140. Such configuration can be done applying the desired values to control units (such as control unit 270 described above) in each multiplexer. In an embodiment, drivers that are connected to the same PLL's output (such as, for example, drivers 115-A1 through 115-AN that would all be connected to the output of PLL 110A via terminal In1) are physically placed close to the corresponding PLL and to each other, and connected to the respective output channel traces (122). Any likely cross-talk between/among the output traces 122 (i.e., traces 122A-122N) is mitigated using standard practices like shielding and/or by careful frequency-planning (for example, the multiplexer can be configured such that output traces that are relatively close to each other do not carry harmonically-unrelated clocks/signals.

In an alternative embodiment, a multiplexer does not have its own in-built control unit such as control unit 270. Instead, a master control unit is implemented within signal distributor 120 and is designed to receive control signals or values from an external device and to generate control signals for configuring each multiplexer to forward a desired input to its output. The implementation details of such a master control unit would be well known to one skilled in the relevant arts upon reading the disclosure herein.

It is noted here that although in the examples herein, the number of PLLs 110 and the number of output pins 140 are noted as being equal, in general their numbers need not be equal. The number of PLLs can be less than, equal to or greater than the number of output pins, as also noted above with respect to the inputs ports and output ports of signal distributor 120. Corresponding modifications can be made to the implementation of signal distributor 120 when the numbers are unequal. For example, if the number of PLLs 110 is less than the number of output pins 140 by one, and it is required to make each PLL's clock signal selectively available at any one of the output pins, then one additional channel is implemented to connect to the additional one output pin. The channel would be connected to the output of an additional MUX, which will contain another set of drivers, each of whose inputs is connected to a corresponding PLL's output.

It is noted here although each driver is described above as being a SST inverter (differential or single-ended) with additional switches at the input for enabling the driver to be used in a multiplexer, in other environments, a driver can be implemented differently from a SST inverter, but with switches at the inputs to enable its use in a multiplexer in a manner described above. Such implementations would be apparent to one skilled in the relevant arts upon reading the disclosure herein.

### 5. Conclusion

References throughout this specification to “one embodiment”, “an embodiment”, or similar language means that a particular feature, structure, or characteristic described in connection with the embodiment is included in at least one embodiment of the present disclosure. Thus, appearances of the phrases “in one embodiment”, “in an embodiment” and similar language throughout this specification may, but do not necessarily, all refer to the same embodiment.

While in the illustrations of FIGS. 1 through 4, although terminals/nodes are shown with direct connections to (i.e., “connected to”) various other terminals, it should be appreciated that additional components (as suited for the specific environment) may also be present in the path, and accordingly the connections may be viewed as being “electrically coupled” to the same connected terminals.

It should be appreciated that the specific type of transistors (such as NMOS, PMOS, etc.) noted above are merely by way of illustration. However, alternative embodiments using different configurations and transistors (e.g., bipolar junction transistor (BJT)) will be apparent to one skilled in the relevant arts by reading the disclosure provided herein. For example, the NMOS transistors may be swapped with PMOS (P-channel MOS) transistors, while also interchanging the connections to power and ground terminals.

Accordingly, in the instant application, the power and ground terminals are referred to as constant reference potentials, the source (emitter) and drain (collector) terminals of transistors (through which a current path is provided when turned ON and an open path is provided when turned OFF) are termed as current terminals, and the gate (base) terminal is termed as a control terminal.

While various embodiments of the present disclosure have been described above, it should be understood that they have been presented by way of example only, and not limitation. Thus, the breadth and scope of the present disclosure should not be limited by any of the above-described embodiments, but should be defined only in accordance with the following claims and their equivalents.

What is claimed is:

1. A multiplexer to connect any of a plurality of input signals to an output path, said multiplexer comprising:
a plurality of transistors, each transistor having a control terminal and a pair of current terminals, one terminal of the pair being coupled to a constant reference potential and the other terminal being coupled to an output node at one end of said output path,
wherein the transistor is operable to provide a forwarded signal at said output node corresponding to a transistor-control signal if the transistor-control signal is received at said control terminal, and to tri-state said output node if said control terminal is coupled to said constant reference potential;
a set of switches; and
a control unit to receive a value indicating a specific transistor of said plurality of transistors which is to provide the corresponding input signal to said output path, said control unit to control the set of switches of the specific transistor to couple the corresponding input signal as said transistor-control signal at the control terminal of the specific transistor,
said control unit controlling the set of switches of remaining ones of said plurality of transistors to provide said constant reference potential to the control terminal of each switch of the remaining ones of said plurality of transistors.

2. The multiplexer of claim 1, wherein said multiplexer comprises a plurality of drivers, with each driver receiving a corresponding input signal and only one of said plurality of drivers providing a corresponding forwarded signal to said output path, wherein each of said plurality of drivers comprises:
a first pair of transistors coupled in series at a first junction and being provided between a first constant reference potential and a second constant reference potential, wherein said constant reference potential is one of said first constant reference potential and said second constant reference potential, wherein said first junction is said output node, wherein each transistor of said plurality of transistor corresponds to one transistor of said first pair of transistors;
a first pair of switches comprised in said set of switches to couple the respective control terminal of each of said first pair of transistors to said corresponding input signal when closed, and to decouple said respective control terminal of each of said first pair of transistors from said corresponding input signal when open; and
a second pair of switches comprised in said set of switches to couple respective control terminals of said first pair of transistors to a corresponding one of said first constant reference potential and a second constant reference potential when closed, and to decouple respective control terminals of said first pair of transistors from said corresponding one of said first constant reference potential and a second constant reference potential when open,
wherein, to cause only the driver containing said specific transistor to forward the corresponding input signal to said output path and to tri-state the output nodes of the remaining ones of said plurality of drivers, said control signal operates:
said first pair of switches of said specific driver to be closed, and each of said first pair of switches of said remaining ones of said plurality of drivers to be open; and
said second pair of switches of said specific driver to be open, and each of said second pair of switches of said remaining ones of said plurality of drivers to be closed.

3. The multiplexer of claim 2, wherein each of said plurality of input signals is a single-ended signal, wherein said output path comprises said output node and one or both of said first constant reference potential and a second constant reference potential.

4. The multiplexer of claim 2, wherein each of said plurality of input signals is a differential signal comprising a first complementary signal and a second complementary signal, wherein said first complementary signal is provided as said transistor-control signal of each of said plurality of transistors, wherein said output path is a differential path, wherein each driver of said plurality of drivers further comprises:
a second pair of transistors coupled in series at a second junction and being provided between said first constant reference potential and said second constant reference potential, wherein said second junction is coupled to said output path at a second output node of said driver, wherein said output node and said second output node together provide an output signal in differential form on said output path;
a third pair of switches to couple said second complementary signal of the corresponding input signal to a control terminal of each of said second pair of transistors when closed, and to decouple said control terminal of each of said second pair of transistors from said second complementary signal of the corresponding input signal when open; and
a fourth pair of switches to couple respective control terminals of said second pair of transistors to a corresponding one of said first constant reference potential and said second constant reference potential when closed, and to decouple respective control terminals of said second pair of transistors from said corresponding one of said first constant reference potential and said second constant reference potential when open,
wherein, to cause only the specific driver containing said specific transistor to forward the corresponding second complementary signal to said output path and to tri-state the output nodes of the remaining ones of said plurality of drivers, said control signal also operates:
said third set of switches of the specific driver to be closed, and each of said third set of switches of said remaining ones of said plurality of drivers to be open; and
said fourth set of switches of said specific driver to be open, and each of said fourth set of switches of said remaining ones of said plurality of drivers to be closed.

5. The multiplexer of claim 4, wherein each driver of said plurality of drivers is a source-series terminated (SST) differential inverter.

6. The multiplexer of claim 5, wherein each of said plurality of drivers further comprises:
a first impedance coupled between a first one of said first pair of transistors and said first junction;
a second impedance coupled between a second one of said first pair of transistors and said first junction;
a third impedance coupled between a first one of said second pair of transistors and said second junction; and
a fourth impedance coupled between a second one of said second pair of transistors and said second junction.

7. The multiplexer of claim 6, wherein magnitudes of said first impedance, said second impedance, said third impedance and said fourth impedance are equal.

8. The multiplexer of claim 7, wherein a differential output impedance of said driver is less than a characteristic impedance of said output path.

9. A signal distributor comprising a first plurality of input ports and a second plurality of output ports, said signal distributor being operable to couple each input port of said first plurality of input ports to any one output port of said plurality of output ports, said signal distributor comprising:
a third plurality of multiplexers, wherein a number of multiplexers in said third plurality of multiplexers equals a number of ports in said second plurality of ports,
wherein each multiplexer in said third plurality of multiplexers has a fourth plurality of input nodes, with each input node coupled to a respective one of said plurality of input ports,
wherein each multiplexer in said third plurality of multiplexers has one output node coupled to a corresponding one of said plurality of output ports,
wherein each multiplexer comprises:
a plurality of transistors, each transistor having a control terminal and a pair of current terminals, one terminal of the pair being coupled to a constant reference potential and the other terminal being coupled to an output node at one end of said output path,
wherein the transistor is operable to provide a forwarded signal at said output node corresponding to a transistor-control signal if the transistor-control signal is received at said control terminal, and to tri-state said output node if said control terminal is coupled to a constant reference potential;
a set of switches; and
a control unit to receive a value indicating a specific transistor of said plurality of transistors which is to provide the corresponding input signal to said output path, said control unit to control the set of switches of the specific transistor to couple the corresponding input signal as said transistor-control signal at the control terminal of the specific transistor,
said control unit controlling the set of switches of remaining ones of said plurality of transistors to provide said constant reference potential to the control terminal of each switch of the remaining ones of said plurality of transistors.

10. The signal distributor of claim 9, wherein said each multiplexer comprises a plurality of drivers, with each driver receiving a corresponding input signal and only one of said plurality of drivers providing a corresponding forwarded signal to said output path, wherein each of said plurality of drivers comprises:
a first pair of transistors coupled in series at a first junction and being provided between a first constant reference potential and a second constant reference potential, wherein said constant reference potential is one of said first constant reference potential and said second constant reference potential, wherein said first junction is said output node, wherein each transistor of said plurality of transistor corresponds to one transistor of said first pair of transistors;
a first pair of switches comprised in said set of switches, to couple the control terminal of each of said first pair of transistors to said corresponding input signal when closed, and to decouple said control terminal of each of said first pair of transistors from said corresponding input signal when open; and
a second pair of switches comprised in said set of switches, to couple respective control terminals of said first pair of transistors to a corresponding one of said first constant reference potential and a second constant reference potential when closed, and to decouple respective control terminals of said first pair of transistors from said corresponding one of said first constant reference potential and a second constant reference potential when open,
wherein, to cause only the driver containing said specific transistor to forward the corresponding input signal to said output path and to tri-state the output nodes of the remaining ones of said plurality of drivers, said control signal operates:
said first pair of switches of said specific driver to be closed, and each of said first pair of switches of said remaining ones of said plurality of drivers to be open; and
said second pair of switches of said specific driver to be open, and each of said second pair of switches of said remaining ones of said plurality of drivers to be closed.

11. The signal distributor of claim 10, wherein each of said plurality of input signals is a single-ended signal, wherein said output path comprises said output node and one or both of said first constant reference potential and a second constant reference potential.

12. The signal distributor of claim 10, wherein each of said plurality of input signals is a differential signal, wherein said output path is a differential path,
wherein each of said plurality of drivers further comprises:
a second pair of transistors coupled in series at a second junction and being provided between said first constant reference potential and said second constant reference potential, wherein said second junction is coupled to said output path at a second output node of said driver;
a third pair of switches to couple a control terminal of each of said second pair of transistors to said corresponding input signal when closed, and to decouple said control terminal of each of said second pair of transistors from said corresponding input signal when open; and
a fourth pair of switches to couple respective control terminals of said second pair of transistors to a corresponding one of said power source and a constant reference potential when closed, and to decouple respective control terminals of said second pair of transistors from said corresponding one of said power source and a constant reference potential when open,
wherein, to cause only the specific driver containing said specific transistor to forward the corresponding second complementary signal to said output path and to tri-state the output nodes of the remaining ones of said plurality of drivers, said control signal also operates:
said third set of switches of said specific driver to be closed, and each of said third set of switches of said remaining ones of said plurality of drivers to be open; and
said fourth set of switches of said specific driver to be open, and each of said fourth set of switches of said remaining ones of said plurality of drivers to be closed.

13. The signal distributor of claim 12, wherein each driver of said plurality of drivers is a source-series terminated (SST) differential inverter.

14. The signal distributor of claim 13, wherein each of said plurality of drivers further comprises:
a first impedance coupled between a first one of said first pair of transistors and said first junction;
a second impedance coupled between a second one of said first pair of transistors and said first junction;
a third impedance coupled between a first one of said second pair of transistors and said second junction; and
a fourth impedance coupled between a second one of said second pair of transistors and said second junction.

15. The signal distributor of claim 14, wherein magnitudes of said first impedance, said second impedance, said third impedance and said fourth impedance are equal.

16. The signal distributor of claim 15, wherein a differential output impedance of said driver is less than a characteristic impedance of said output path.

17. The signal distributor of claim 16, wherein the number of inputs ports in said first plurality of ports is equal to the number of output ports in said second plurality of ports.

18. The signal distributor of claim 16, wherein the number of inputs ports in said first plurality of ports is different from the number of output ports in said second plurality of ports.
